(19) United States
(12) Patent Application Publication
(10) Pub. No.: US 2017/0300152 A1
(43) Pub. Date: Oct. 19, 2017

(54) TOUCH CONTROL DISPLAY MODULE AND DISPLAY DEVICE

(71) Applicant: Shenzhen China Star Optoelectronics Technology Co., Ltd., Shenzhen, Guangdong (CN)

(72) Inventor: Chengliang YE, Shenzhen, Guangdong (CN)

(73) Assignee: Shenzhen China Star Optoelectronics Technology Co., Ltd., Shenzhen, Guangdong (CN)

(21) Appl. No.: 14/407,935

(22) PCT Filed: Nov. 21, 2014
(86) PCT No.: PCT/CN2014/091891

§ 371 Date: Jun. 4, 2017

(30) Foreign Application Priority Data
Nov. 18, 2014 (CN) 201410660274.3

(51) Int. Cl. G06F 3/041; H01L 27/32; G06F 3/044; G02F 1/1343; G02F 1/1333; G09G 3/3225; G09G 3/36

(52) U.S. Cl. CPC G06F 3/0412; G02F 1/1343; H01L 27/323; G02F 1/13338; G06F 3/044; G09G 3/3648; G09G 3/3225

(57) ABSTRACT

Touch control display module and display device are provided. The touch control display module includes opposite upper and lower substrates and a liquid crystal layer between the upper and lower substrates. Inner sides of the upper and lower substrates respectively are disposed with first and second strip electrodes. Extending directions of first and second strip electrodes are intersected with each other. The module further includes a control chip connected with the first and second strip electrodes, when performs a 3D display, the control chip drives the first and second strip electrodes to achieve a function of liquid crystal lens or liquid crystal grating, and when performs a 2D display, the control chip drives the first and second strip electrodes to achieve a function of positioning a touch operation. The module can perform 3D display and achieve touch positioning function in 2D display without additional touch control layer.

### TECHNICAL FIELD

The invention relates to the field of display technology, and particularly to a touch control display module and a touch control display device.

### DESCRIPTION OF RELATED ART

At present, the 3D display technology has attracted much attention. A basic principle of 3D display is that using the left and right eyes to receive different images and then forming a 3D image after the brain processes the received image information. In order to achieve 3D display, in the prior art, a layer of naked-eye 3D grating is added on a display screen. The naked-eye 3D grating has two types, i.e., parallax barrier and cylindrical lens grating. The 3D implementation process of the gating is that a liquid crystal box is added on an original display screen. The liquid crystal box includes a first substrate, a second substrate and a liquid crystal layer filled between the first and second substrate. By modulating an electric field formed by the first substrate and the second substrate to make liquid crystal molecules to tilt along a certain direction to thereby form a lens-like effect, so that light of the display screen is converged along a certain direction to form multiple (i.e., more than one) different viewing zones, a left eye image and a right eye image respectively are transmitted to human left eye and right eye and thereby can feel the 3D effect. Or, the liquid crystal layer forms a structure similar to a parallax barrier under the effect of electric field, so that the left and right eyes can receive different images and thereby feel the 3D effect.

On the basis of rapid development of 3D display technology and touch control technology, a display screen can achieve both 3D display and touch operation positioning has been proposed, a structure thereof is that the 3D display screen is additionally added with a touch control layer. For such structure, its production process is relatively complex, its production cost is high, it will additionally increase the thickness of the display screen and the additionally added touch control layer would affect the emergence of light, i.e., affect the transmittance of the display screen.

### SUMMARY

A technical problem primarily to be solved by the invention is to provide a touch control display module and a touch control display device, which is capable of performing 3D display and achieving touch positioning function in 2D display without the additional touch control layer, and therefore is in favor of transmittance and slim design of display module.

In order to solve the technical problem, the invention provides a touch control display module. The touch control display module includes: an upper substrate, a lower substrate disposed opposite to the upper substrate, and a liquid crystal layer disposed between the upper substrate and the lower substrate. A side of the upper substrate facing the lower substrate is disposed with first strip electrodes, and a side of the lower substrate facing the upper substrate is disposed with second strip electrodes. An extending direction of the first strip electrodes and an extending direction of the second strip electrodes are mutually perpendicular to each other. The touch control display module further includes a control chip connected with the first strip electrodes and the second strip electrodes, when performs a 3D display, the control chip is configured (i.e., structured and arranged) for driving the first strip electrodes and the second strip electrodes to thereby achieve a function of liquid crystal lens or liquid crystal grating, and when performs a 2D display, the control chip is configured for driving the first strip electrodes and the second strip electrodes to thereby achieve a function of positioning a touch operation. Each neighboring two of the first strip electrodes have a same spacing distance being a first distance as another neighboring two of the first strip electrodes, each neighboring two of the second strip electrodes have a same spacing distance being a second distance as another neighboring two of the second strip electrodes, the first distance is larger than the second distance. The first strip electrodes have a same width being a first width, the second strip electrodes have a same width being a second width, and the first width is smaller than the second width.

In an exemplary embodiment, when performs the 2D display, the control chip further is configured for driving the first strip electrodes and the second strip electrodes to form mutual-capacitors to thereby achieve the function of positioning the touch operation.

In an exemplary embodiment, the first strip electrodes and the second strip electrodes are indium tin oxide (ITO) electrodes.

In order to solve the above technical problem, the invention provides another touch control display module. The touch control display module includes an upper substrate, a lower substrate disposed opposite to the upper substrate, and a liquid crystal layer disposed between the upper substrate and the lower substrate. A side of the upper substrate facing the lower substrate is disposed with first strip electrodes, and a side of the lower substrate facing the upper substrate is disposed with second strip electrodes. An extending direction of the first strip electrodes and an extending direction of the second strip electrodes are mutually intersected with each other. The touch control display module further includes a control chip connected with the first strip electrodes and the second strip electrodes, when performs a 3D display, the control chip is configured for driving the first strip electrodes and the second strip electrode to thereby achieve a function of liquid crystal lens or liquid crystal grating, and when performs a 2D display, the control chip is configured for driving the first strip electrodes and the second strip electrodes to thereby achieve a function of positioning a touch operation.

In an exemplary embodiment, the extending direction of the first strip electrodes and the extending direction of the second strip electrodes are mutually perpendicular to each other.

In an exemplary embodiment, each neighboring two of the first strip electrodes have a same spacing distance being a first distance as another neighboring two of the first strip electrodes, each neighboring two of the second strip electrodes have a same spacing distance being a second distance as another neighboring two of the second strip electrodes, the first distance is larger than the second distance. The first strip electrodes have a same width being a first width, the second strip electrodes have a same width being a second width, and the first width is smaller than the second width.

In an exemplary embodiment, when performs the 2D display, the control chip further is configured for driving the first strip electrodes and the second strip electrodes to form mutual-capacitors to thereby achieve the function of positioning the touch operation.

In an exemplary embodiment, the first strip electrodes and the second strip electrodes are indium tin oxide (ITO) electrodes.

In order to solve the above technical problem, the invention provides a touch control display device. The touch control display device includes a touch control display module and a display panel, the display panel is disposed below the touch control display module. The touch control display module includes an upper substrate, a lower substrate disposed opposite to the upper substrate, and a liquid crystal layer disposed between the upper substrate and the lower substrate. A side of the upper substrate facing the lower substrate is disposed with first strip electrodes, and a side of the lower substrate facing the upper substrate is disposed with second strip electrodes. An extending direction of the first strip electrodes and an extending direction of the second strip electrodes are mutually intersected with each other. The touch control display module further includes a control chip connected with the first strip electrodes and the second strip electrodes, when performs a 3D display, the control chip is configured for driving the first strip electrodes and the second strip electrodes to thereby achieve a function of liquid crystal lens or liquid crystal grating, and when performs a 2D display, the control chip is configured for driving the first strip electrodes and the second strip electrodes to thereby achieve a function of positioning a touch operation.

In an exemplary embodiment, the extending direction of the first strip electrodes and the extending direction of the second strip electrodes are mutually perpendicular to each other.

In an exemplary embodiment, each neighboring two of the first strip electrodes have a same spacing distance being a first distance as another neighboring two of the first strip electrodes, each neighboring two of the second strip electrodes have a same spacing distance being a second distance as another neighboring two of the second strip electrodes, the first distance is larger than the second distance. The first strip electrodes have a same width being a first width, the second strip electrodes have a same width being a second width, and the first width is smaller than the second width.

In an exemplary embodiment, when performs the 2D display, the control chip further is configured for driving the first strip electrodes and the second strip electrodes to form mutual-capacitors to thereby achieve the function of positioning the touch operation.

In an exemplary embodiment, the display panel is a liquid crystal display (LCD) panel, an organic light-emitting diode (OLED) display panel, a plasma display panel (PDP), or a cathode ray tube (CRT) display panel.

The efficacy of the invention is that: different from the prior art, the touch control display module of the invention includes oppositely disposed upper and lower substrates and a liquid crystal layer between the upper and lower substrates, disposes mutually intersected strip electrodes respectively on the upper substrate and the lower substrate and uses a control chip to drive and control two kinds of strip electrodes to make the liquid crystal layer to exhibit lens or grating effect, and thereby the touch control display module can achieve 3D display. Since the 3D display has a large energy consumption, in the actual use of process, when it does not perform the 3D display but performs a 2D display, the touch control display module is reused, that is, the control chip uses another mode to drive and control the two kinds of strip electrodes to make the touch control display module to achieve a function of positioning a touch operation. Accordingly, the invention can perform the 3D display and also can achieve touch positioning function in 2D display without additional touch control layer, and therefore is in favor of transmittance and slim design of display module.

### BRIEF DESCRIPTION OF THE DRAWINGS

In order to more clearly illustrate the technical solutions of various embodiments of the present invention, drawings will be used in the description of embodiments will be given a brief description below. Apparently, the drawings in the following description only are some embodiments of the invention, the ordinary skill in the art can obtain other drawings according to these illustrated drawings without creative effort. In the drawings:

FIG. 1 is a schematic structural view of a first embodiment of a touch control display module of the invention;

FIG. 2 is a schematic structural view of first strip electrodes and second strip electrodes in the first embodiment of the touch control display module as shown in FIG. 1;

FIG. 3 is a schematic view of a connection manner of a control chip with first strip electrodes or second strip electrodes in the first embodiment of the touch control display module as shown in FIG. 1;

FIG. 4 is a schematic view of liquid crystal molecules deflected along directions of electric field lines to achieve a liquid crystal lens function in the first embodiment of the touch control display module as shown in FIG. 1;

FIG. 5 is a schematic principle diagram of implementing a 3D display under the situation of the liquid crystal layer forming a cylindrical lens structure in the first embodiment of the touch control display module in FIG. 1;

FIG. 6 is a schematic view of applying scan signals to first strip electrodes and second strip electrodes in a self-capacitive operation mode in the first embodiment of the touch control display module as shown in FIG. 1;

FIG. 7 is a schematic circuit diagram of a first strip electrode and a second strip electrode in a self-capacitive operation mode in the first embodiment of the touch control display module as shown in FIG. 1;

FIG. 8 is a schematic view of applying scan signals to first strip electrodes or second strip electrodes in a mutual-capacitive operation mode in the first embodiment of the touch control display module as shown in FIG. 1;

FIG. 9 is a schematic circuit diagram of a first strip electrode and a second strip electrode in a mutual-capacitive operation mode in the first embodiment of the touch control display module as shown in FIG. 1;

FIG. 10 is a schematic structural view of a second embodiment of a touch control display module of the invention;

FIG. 11 is a schematic structural view of a first embodiment of a touch control display device of the invention.

### DETAILED DESCRIPTION OF EMBODIMENTS

In the following, with reference to accompanying drawings of embodiments of the invention, technical solutions in the embodiments of the invention will be clearly and completely described. Apparently, the embodiments of the invention described below only are a part of embodiments of the invention, but not all embodiments. Based on the described embodiments of the invention, all other embodiments obtained by ordinary skill in the art without creative effort belong to the scope of protection of the invention.

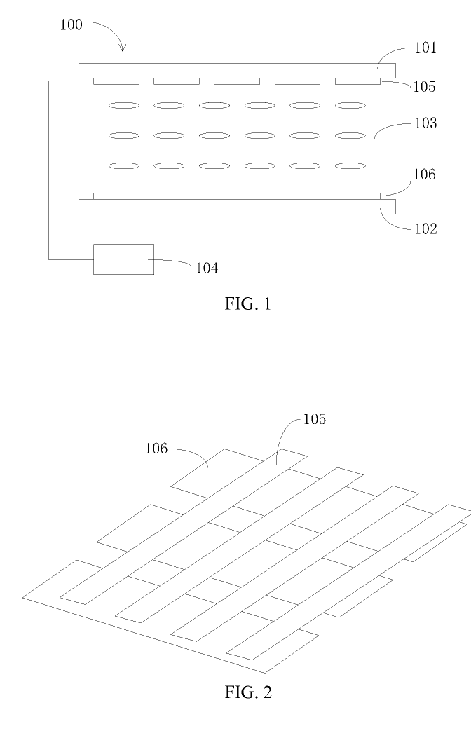

Referring to FIGS. 1 and 2, FIG. 1 is a schematic structural view of a first embodiment of a touch control display module of the invention, and FIG. 2 is a schematic structural view of first strip electrodes and second strip electrodes in the first embodiment of the touch control display module as shown in FIG. 1. In particular, this embodiment provides a touch control display module 100 including an upper substrate 101, a lower substrate 102, a liquid crystal layer 103 and a control chip 104.

The upper substrate 101 and the lower substrate 102 are oppositely disposed. The liquid crystal layer 103 is disposed between the upper substrate 101 and the lower substrate 102. A side of the upper substrate 101 facing the lower substrate 102 is disposed with first strip electrodes 105, and a side of the lower substrate 102 facing the upper substrate 101 is disposed with second strip electrodes 106. An extending direction of the first strip electrodes 105 and an extending direction of the second strip electrodes 106 are mutually intersected with each other.

In order to obtain a large viewing angle in 3D display, in this embodiment, the liquid crystal layer 103 has a thickness of 100 micrometers (μm), the upper substrate 101 and the lower substrate 102 both are glass substrates with a thickness of 0.5 millimeters (mm). ITO film layers act as electrically conductive electrodes overlaid on the glass substrates and have the advantages of good conductivity and high transparency. In other embodiment, the thickness of the liquid crystal layer 103 can be set as 50 μm, 30 μm or 20 μm instead, and thus the thickness of the liquid crystal layer 103 is not limited herein. Based on actual application, for different requirements of viewing angle, correspondingly different thicknesses of liquid crystal layer are set.

Because the light finally needs to pass through the touch control display module for achieving the purpose of display, the upper substrate 101 and the lower substrate 102 are made of a transparent material. Since the glass substrate is mature and can achieve high transmittance, and therefore the glass substrate is used in this embodiment. Of course, if pursuing a more lightweight design, transparent plastic or other transparent polymer can be used instead. At present, based on different thicknesses, glass substrates in mass production can classified into the following several specifications that: 2.0 mm, 1.1 mm, 0.7 mm, 0.5 mm, 0.4 mm and 0.3 mm. When cost and application requirement are taken in consideration, the glass substrate with a thickness of 0.5 mm is used in this embodiment. Technicians can use a glass substrate with other thickness based on actual requirement or customize a glass substrate with a certain thickness such as 0.2 mm or 3.0 mm, and so on.

In this embodiment, the ITO film layers are overlaid on the glass substrates to form the strip electrodes, and an extending direction (i.e., generally lengthwise direction) of the first strip electrodes and an extending direction (i.e., generally lengthwise direction) of the second strip electrodes are mutually intersected with each other. A main component of the ITO film layers is indium tin oxide, the indium oxide has a high transmittance, and the tin oxide has a good conductivity. If the required light transmittance of the touch control display module is not high, conductive glue or conductive tape, etc., can be used instead.

The control chip 104 is connected with the first strip electrodes 105 and the second strip electrodes 106.

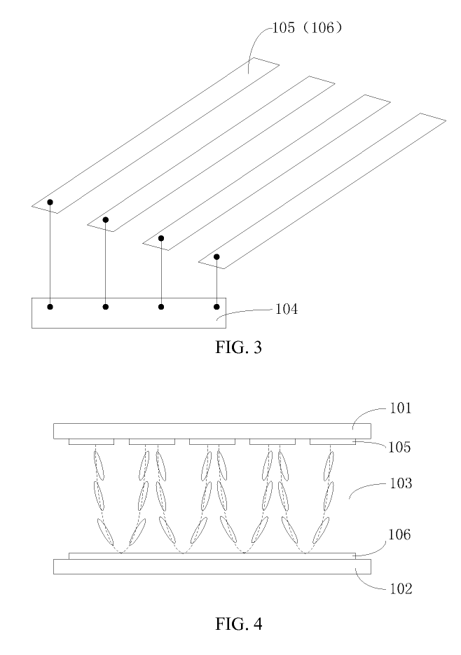

In this embodiment, the connection of the control chip 104 with the first strip electrodes 105 and the second strip electrodes 106 is carried out by a wire bonding technique, i.e., fine metal wires (a diameter is about 3 μm) are used to connect a circuit of the control chip 104 with the first strip electrodes 105 or the second strip electrodes 106 by ultrasonic welding or hot pressure welding. Concretely, please refer to FIG. 3, FIG. 3 is a schematic view of the connection manner of the control chip with the first strip electrodes or the second strip electrodes in the first embodiment of the touch control display module as shown in FIG. 1. Herein, the adopted connection technique is not limited.

The touch control display module 100 has two display modes, i.e., 3D display and 2D display. When performs a 3D display, the control chip 104 drives the first strip electrodes 105 and the second strip electrodes 106 to thereby achieve a function of liquid crystal lens or liquid crystal grating.

In this embodiment, the control chip 104 drives the first strip electrodes 105 and the second strip electrodes 106 to form a potential difference therebetween, so as to make the liquid crystal layer 103 to achieve the function of liquid crystal lens. Since the liquid crystal molecules in the liquid crystal layer 103 have the characteristic that molecular potential energy tends to change toward the lowest state, i.e., the long axis of liquid crystal molecule is consistent with a field strength direction of an externally applied electric field. Based on this principle, when an electric filed is applied onto the liquid crystal layer 103, the function of liquid crystal lens can be achieved. Concretely, please refer to FIG. 4, FIG. 4 is a schematic view of liquid crystal molecules deflected along directions of electric field lines for achieving the function of liquid crystal lens in the first embodiment of the touch control display module as shown in FIG. 1. The control chip 104 applies voltages onto the first strip electrodes 105 and the second strip electrodes 106 to form an electric field, and makes the second strip electrodes 106 to be at a Com potential. The liquid crystal molecules in the liquid crystal layer 103 are deflected under the effect of the electric field to form a structure similar to a cylindrical lens to thereby achieve a light converging function.

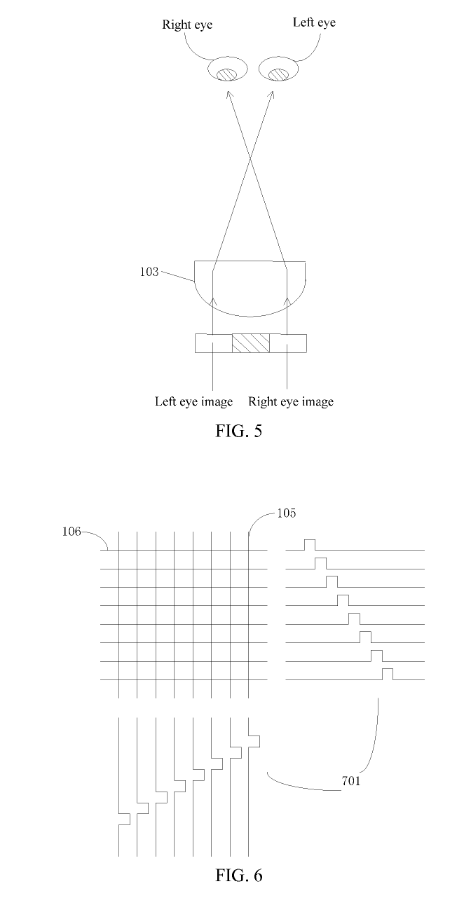

In the case of the liquid crystal layer 103 being a cylindrical lens structure, lights can pass through the liquid crystal layer 103 and then are transmitted into human left eye and right eye respectively, so that the 3D display is achieved. Concretely, please refer to FIG. 5, FIG. 5 is a schematic principle diagram of achieving a 3D display in the case of the liquid crystal layer forming a cylindrical lens structure in the first embodiment of the touch control display module as shown in FIG. 1. At this situation, light corresponding to the left eye image would be converged to human left eye, and light corresponding to the right eye image would be converged to human right eye, and thereby achieving the 3D display.

In other embodiment, the control chip 104 can drive the first strip electrodes 105 and the second strip electrodes 106 to generate a potential difference therebetween, so as to make the liquid crystal layer 103 to achieve a function of liquid crystal grating. That is, the liquid crystal molecules form a structure similar to a parallax barrier under the effect of electric field, so that a left eye image displayed by odd pixel columns of the display panel can be transmitted to the left eye, and a right eye image displayed by even pixel columns can be transmitted to the right eye, and thereby achieving the 3D display.

When performs a 2D display, the control chip 104 drives the first strip electrodes 105 and the second strip electrodes 106 to thereby achieve a function of positioning a touch operation.

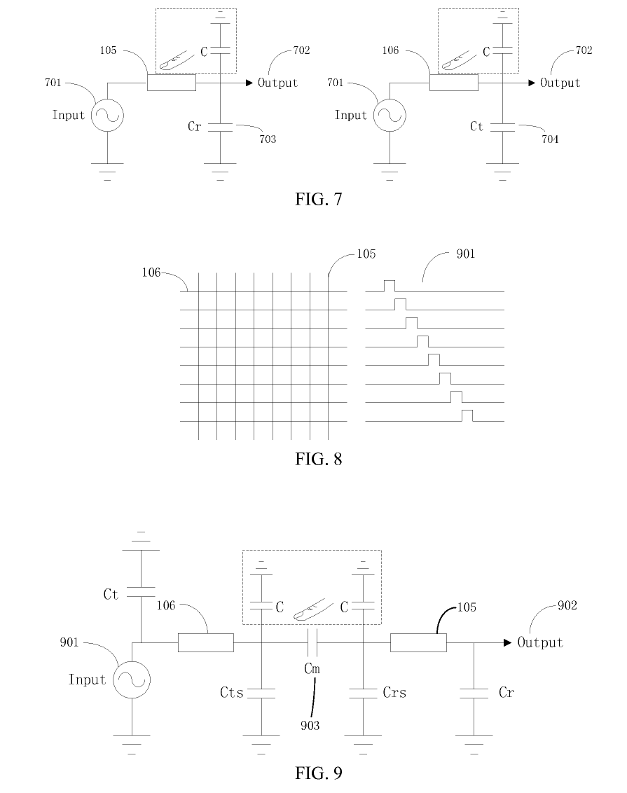

The achievement of touch operation positioning has two operation modes, i.e., self-capacitive and mutual-capacitive. For the self-capacitive operation mode, please refer to FIG. 6 and FIG. 7, FIG. 6 is a schematic view of applying scan signals onto first strip electrodes and second strip electrodes in the self-capacitive operation mode in the first embodiment of the touch control display module as shown in FIG. 6, and FIG. 7 is a schematic circuit diagram of the first strip electrode and the second strip electrode in the self-capacitive operation mode in the first embodiment of the touch control display module as shown in FIG. 1.

In the self-capacitive operation mode, the control chip 104 inputs a scan signal Input701 to the first strip electrode 105 and the second strip electrode 106, the first strip electrode 105 and the second strip electrode 106 simultaneously receive touch control signals Output702, a self-capacitor Cr703 of the first strip electrode 105 and a self-capacitor Ct704 of the second strip electrode 106 then are detected, and herein the self-capacitors each are a capacitor formed by electrode and ground. If the amount/number of the first strip electrodes 105 is m, and the number of the second strip electrodes 106 is n, the number of self-capacitors needed to be detected is (m+n). When a touch occurs, the first strip electrode 105 and the second strip electrode 106 which a touch point is located on respectively receive signals of capacitance change, the first strip electrode 105 and the second strip electrode 106 which the touch point is located on then can be determined respectively, and an intersection point of the two strip electrodes can be inferred as the touch point. When adopts this self-capacitive operation mode, in multi-touch, the problem of touch points being uncertain would be easily occurs. For example, for a two-point touch, two first strip electrodes 105 and two second strip electrodes 106 are determined simultaneously, but they have four intersection points, and therefore it is unable to determine actual touch points are which two of the four intersection points.

For the mutual-capacitive operation mode, please refer to FIG. 8 and FIG. 9, FIG. 8 is a schematic view of applying scan signals onto first strip electrodes or second strip electrodes in the mutual-capacitive operation mode in the first embodiment of the touch control display module as shown in FIG. 1, and FIG. 9 is a schematic circuit diagram of the first strip electrode and the second strip electrode in the mutual-capacitive operation mode in the first embodiment of the touch control display module as shown in FIG. 1.

In the mutual-capacitive operation mode, the control chip 104 inputs a scan signal Input901 to the second strip electrode 106, the first strip electrode 106 receive a touch control signal Output902 at the same time, a mutual-capacitor Cm903 at the intersection of the first strip electrode 105 with the second strip electrode 106 then is detected, and the mutual-capacitor Cm903 herein is a capacitor formed by two electrodes. If the number of the first strip electrodes 105 is m, the number of the second strip electrodes 106 is n, the number of mutual-capacitors needed to be detected is (m×n). When a touch occurs, a touch point can be determined according to detected capacitance at the intersection. When adopts this mutual-capacitive operation mode, points needed to be detected are excessive and therefore the operating efficiency is low.

In order to truly achieve multi-touch, this embodiment adopts the mutual-capacitive operation mode. In other embodiment, the self-capacitive operation mode may be adopted, or an operation mode of the combination of self-capacitive and mutual-capacitive may be adopted.

Different from the prior art, the touch control display module in this embodiment includes oppositely disposed upper and lower substrates and a liquid crystal layer between the upper and lower substrates, disposes mutually intersected strip electrodes respectively on the upper substrate and the lower substrate and uses a control chip to drive and control the strip electrodes to make the liquid crystal layer achieve the lens or grating effect, and thereby the touch control display module can achieve the 3D display. Moreover, when it does not perform the 3D display but performs a 2D display, the touch control display module still is used, i.e., the control chip uses another mode to drive and control the electrodes, so as to make the touch control display module to achieve the function of positioning a touch operation. Accordingly, this embodiment can perform the 3D display and also can achieve the touch positioning function in 2D display without the additional touch control layer, and therefore is in favor of transmittance and slim design of display module.

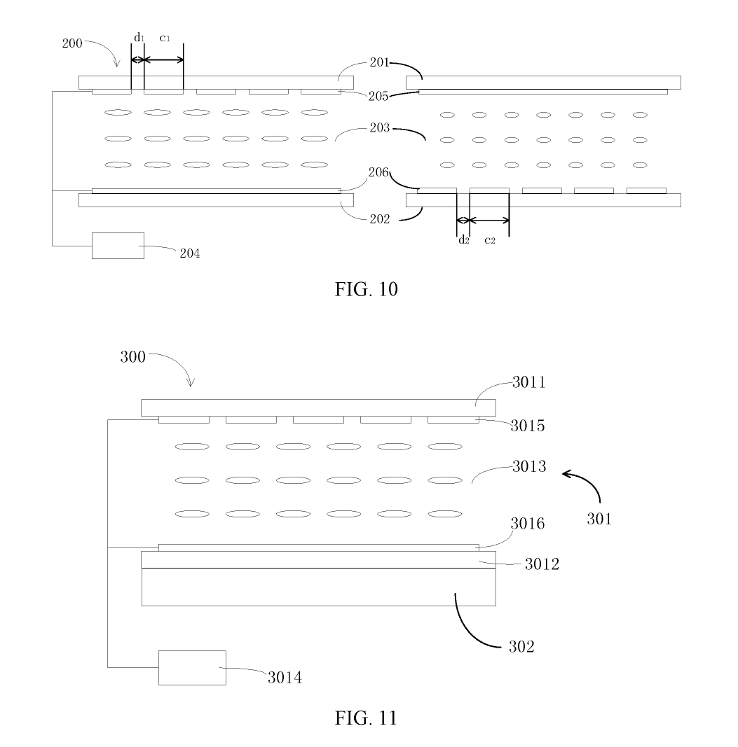

Referring to FIG. 10, FIG. 10 is a schematic structural view of a second embodiment of a touch control display module of the invention. The second embodiment provides a touch control display module 200 including an upper substrate 201, a lower substrate 202, a liquid crystal layer 203 and a control chip 204.

The upper substrate 201 and the lower substrate 202 are disposed oppositely. The liquid crystal layer 203 is disposed between the upper substrate 201 and the lower substrate 202. A side of the upper substrate 201 facing the lower substrate 202 is disposed with first strip electrodes 205, and a side of the lower substrate 202 facing the upper substrate 201 is disposed with second strip electrodes 206. An extending direction of the first strip electrodes 205 and an extending direction of the second strip electrodes 206 are mutually intersected with each other.

The control chip 204 is connected with the first strip electrodes 205 and the second strip electrodes 206. When performs a 3D display, the control chip 204 drives the first strip electrodes 205 and the second strip electrodes 206 to thereby achieve a function of liquid crystal lens or liquid crystal grating. When performs a 2D display, the control chip 204 drives the first strip electrodes 205 and the second strip electrodes 206 to thereby achieve a function of positioning a touch operation.

In this embodiment, structures and arrangements of the upper substrate 201, the lower substrate 202, the liquid crystal layer 203, the control chip 204, the first strip electrodes 205 and the second strip electrodes 206 are similar to that in the first embodiment of the touch control display module, and thus will not be repeated herein.

It should be further described that, in this embodiment, the extending direction of the first strip electrodes 205 and the extending direction of the second strip electrodes 206 are mutually perpendicular to each other. The mutually-perpendicular disposition of two kinds of electrodes is more favorable for the positioning of touch operation.

A spacing distance of each neighboring two first strip electrodes 205 is same as that of another neighboring two first strip electrodes 205, and the spacing distance is a first distance d₁. A spacing distance of each neighboring two second strip electrodes 206 is same as that of another neighboring two second strip electrodes 206, and the spacing distance is a second distance d₂. The first distance d1 is larger than the second distance d₂. All the first strip electrodes 205 have a same width, and the width is a first width c₁. All the second strip electrodes 206 have a same width, and the width is a second width c₂. The first width c₁ is smaller than the second width c₂.

The second width c₂ is set to be relatively larger and the second distance d₂ is set to be relatively smaller, which are in order to not affect an electric field formed between the upper and lower substrates in a 3D display process. If the first width c₁ and the second width c₂ are set to be the same, and the first distance d₁ and the second distance d₂ also are set to be the same, it will be not easy to form a regular electric field, i.e., it is unable to effectively achieve the function of liquid crystal lens or liquid crystal grating.

Different from the prior art, the touch control display module in this embodiment includes oppositely disposed upper and lower substrates and a liquid crystal layer between the upper and lower substrates, disposes mutually intersected strip electrodes on the upper substrate and the lower substrate respectively and uses a control chip to drive and control two kinds of strip electrodes to make the liquid crystal layer to achieve the lens or grating effect and thereby the touch control display module can achieve a 3D display. Moreover, when it does not perform the 3D display but performs a 2D display, the touch control display module still is used, that is, the control chip uses another mode to drive and control the two kinds of strip electrodes, so that the touch control display module can achieve the function of positioning a touch operation. Accordingly, this embodiment can perform the 3D display and also can achieve the touch positioning function without the additional touch control layer, and therefore is in favor of transmittance and slim design of display module. In addition, the second strip electrodes in this embodiment are set with the larger width and the narrower spacing distance with respect to the first strip electrodes, which can achieve the function of liquid crystal lens better.

Referring to FIG. 11, FIG. 11 is a schematic structural view of a first embodiment of a touch control display device of the invention. In particular, this embodiment provides a display device 300 including a touch control display module 301 and a display panel 302.

The touch control display module 301 includes an upper substrate 3011, a lower substrate 3012, a liquid crystal layer 3013, a control chip 3014, first strip electrodes 3015, and second strip electrodes 3016. The touch control display module 301 in this embodiment is similar to the touch control display module 200 as described in the above second embodiment, and thus will not be repeated herein.

The display panel 302 is disposed below the touch control display module 301. When performs a 3D display, the display panel 302 displays an left eye image and an right eye image, the left eye image and the right eye image then respectively are transmitted into human left eye and right eye by the touch control display module 301, and thereby a 3D display effect is exhibited. When performs a 2D display, the display panel 302 displays a 2D image, the 2D image then is transmitted to human eyes by the touch control display module 302, and thereby a 2D display effect is exhibited.

In this embodiment, the display panel is a liquid crystal display (LCD) panel. In other embodiment, the display panel may be an organic light-emitting diode (OLED) display panel, a plasma display panel (PDP) or a cathode ray tube (CRT) display panel.

Different from the prior art, in this embodiment, when the display device performs a 3D display, the display panel sends left eye image and right eye image and meanwhile the control chip in the touch control display module drives two kinds of strip electrodes to make the liquid crystal layer to exhibit lens or grating effect, the left eye image then is transmitted to human left eye and the right eye image is transmitted to human right eye, and thereby the 3D display is achieved. When it does not perform the 3D display but performs a 2D display, the control chip in the touch control display module uses another mode to drive and control the two kinds of strip electrodes to make the touch control display module to achieve the function of positioning a touch operation. Accordingly, this embodiment can perform the 3D display and also can achieve touch positioning function in 2D display without the additional touch control layer, and therefore is in favor of the transmittance and slim design of display module.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A touch control display module comprising: an upper substrate, a lower substrate disposed opposite to the upper substrate, and a liquid crystal layer disposed between the upper substrate and the lower substrate;
wherein a side of the upper substrate facing the lower substrate is disposed with first strip electrodes, a side of the lower substrate facing the upper substrate is disposed with second strip electrodes, an extending direction of the first strip electrodes and an extending direction of the second strip electrodes are mutually perpendicular to each other;
wherein the touch control display module further comprises a control chip connected with the first strip electrodes and the second strip electrodes, when performs a 3D display, the control chip is configured for driving the first strip electrodes and the second strip electrodes to thereby achieve a function of liquid crystal lens or liquid crystal grating, and when performs a 2D display, the control chip is configured for driving the first strip electrodes and the second strip electrodes to thereby achieve a function of positioning a touch operation;
each neighboring two of the first strip electrodes have a same spacing distance being a first distance as another neighboring two of the first strip electrodes, each neighboring two of the second strip electrodes have a same spacing distance being a second distance as another neighboring two of the second strip electrodes, the first distance is larger than the second distance;
the first strip electrodes have a same width being a first width, the second strip electrodes have a same width being a second width, the first width is smaller than the second width.

2. The touch control display module as claimed in claim 1, wherein, when performs the 2D display, the control chip further is configured for driving the first strip electrodes and the second strip electrodes to form mutual-capacitors to thereby achieve the function of positioning the touch operation.

3. The touch control display module as claimed in claim 1, wherein the first strip electrodes and the second strip electrodes are indium tin oxide (ITO) electrodes.

4. A touch control display module comprising: an upper substrate, a lower substrate disposed opposite to the upper substrate, and a liquid crystal layer disposed between the upper substrate and the lower substrate;
wherein a side of the upper substrate facing the lower substrate is disposed with first strip electrodes, a side of the lower substrate facing the upper substrate is disposed with second strip electrodes, an extending direction of the first strip electrodes and an extending direction of the second strip electrodes are mutually intersected with each other;
wherein the touch control display module further comprises a control chip connected with the first strip electrodes and the second strip electrodes, when performs a 3D display, the control chip is configured for driving the first strip electrodes and the second strip electrode to thereby achieve a function of liquid crystal lens or liquid crystal grating, and when performs a 2D display, the control chip is configured for driving the first strip electrodes and the second strip electrodes to thereby achieve a function of positioning a touch operation.

5. The touch control display module as claimed in claim 4, wherein the extending direction of the first strip electrodes and the extending direction of the second strip electrodes are mutually perpendicular to each other.

6. The touch control display module as claimed in claim 4, wherein each neighboring two of the first strip electrodes have a same spacing distance being a first distance as another neighboring two of the first strip electrodes, each neighboring two of the second strip electrodes have a same spacing distance being a second distance as another neighboring two of the second strip electrodes, the first distance is larger than the second distance;
the first strip electrodes have a same width being a first width, the second strip electrodes have a same width being a second width, and the first width is smaller than the second width.

7. The touch control display module as claimed in claim 4, wherein when performs the 2D display, the control chip further is configured for driving the first strip electrodes and the second strip electrodes to form mutual-capacitors to thereby achieve the function of positioning the touch operation.

8. The touch control display module as claimed in claim 4, wherein the first strip electrodes and the second strip electrodes are indium tin oxide (ITO) electrodes.

9. A touch control display device comprising a touch control display module and a display panel, the display panel being disposed below the touch control display module;
wherein the touch control display module comprises an upper substrate, a lower substrate disposed opposite to the upper substrate, and a liquid crystal layer disposed between the upper substrate and the lower substrate;
wherein a side of the upper substrate facing the lower substrate is disposed with first strip electrodes, a side of the lower substrate facing the upper substrate is disposed with second strip electrodes, an extending direction of the first strip electrodes and an extending direction of the second strip electrodes are mutually intersected with each other;
wherein the touch control display module further comprises a control chip connected with the first strip electrodes and the second strip electrodes, when performs a 3D display, the control chip is configured for driving the first strip electrodes and the second strip electrodes to thereby achieve a function of liquid crystal lens or liquid crystal grating, and when performs a 2D display, the control chip is configured for driving the first strip electrodes and the second strip electrodes to thereby achieve a function of positioning a touch operation.

10. The display device as claimed in claim 9, wherein the extending direction of the first strip electrodes and the extending direction of the second strip electrodes are mutually perpendicular to each other.

11. The display device as claimed in claim 9, wherein each neighboring two of the first strip electrodes have a same spacing distance being a first distance as another neighboring two of the first strip electrodes, each neighboring two of the second strip electrodes have a same spacing distance being a second distance as another neighboring two of the second strip electrodes, the first distance is larger than the second distance;
the first strip electrodes all have a same width being a first width, the second strip electrodes all have a same width being a second width, and the first width is smaller than the second width.

12. The display device as claimed in claim 9, wherein when performs the 2D display, the control chip further is configured for driving the first strip electrodes and the second strip electrodes to form mutual-capacitors to thereby achieve the function of positioning the touch operation.

13. The display device as claimed in claim 9, wherein the display panel is a liquid crystal display (LCD) panel, an organic light-emitting diode (OLED) display panel, a plasma display panel (PDP), or a cathode ray tube (CRT) display panel.
